(19) United States
(12) Patent Application Publication
(10) Pub. No.: US 2013/0119536 A1
(43) Pub. Date: May 16, 2013

(54) METHOD FOR FORMING STUDS USED FOR SELF-ALIGNMENT OF SOLDER BUMPS

(71) Applicant: International Business Machines Corporation, Armonk, NY (US)

(72) Inventors: Sayuri Hada, Tokyo (JP); Katsuyuki Sakuma, Fishkill, NY (US); Kuniaki Sueoka, Kanagawa-ken (JP); Kazushige Toriyama, Kanagawa (JP)

(73) Assignee: International Business Machines Corporation, Armonk, NY (US)

(21) Appl. No.: 13/677,538

(22) Filed: Nov. 15, 2012

(30) Foreign Application Priority Data
Nov. 15, 2011 (JP) 2011-249892

(51) Int. Cl. H01L 23/00

(52) U.S. Cl. CPC H01L 24/11; H01L 24/14
USPC 257/737; 438/615

(57) ABSTRACT

A method and a combination of studs, silicon chips, and solder bumps configured to restrict motion of a plurality of silicon chips. The combination includes: a plurality of studs, a plurality of silicon chips, a plurality of target solder bumps, where the plurality of solder bumps are melted between the plurality of silicon chips, where lateral positions of the plurality of studs are in accord with a pitch of the plurality of target solder bumps by using the pitch as a reference, where (i) lateral positions and lateral widths of studs of the plurality of studs located at a first silicon chip of the plurality of silicon chips and (ii) lateral positions and lateral widths of studs of the plurality of studs located at a second silicon chip of the plurality of silicon chips are restricted such that relative lateral motion on the respective silicon chips is restricted.

### CROSS-REFERENCE TO RELATED APPLICATION

This application claims priority under 35 U.S.C. §119 from Japanese patent application No. 2011-249892 filed Nov. 15, 2011, the entire contents of which are incorporated herein by reference.

### BACKGROUND OF THE INVENTION

1. Field of the Invention

The present invention relates to studs used for self-alignment of solder bumps, a method for forming the studs, and a method for bringing multiple silicon chips into alignment by using the studs. More particularly, the present invention relates to a method and a configuration for restricting lateral relative motion of silicon chips when solder bumps are melted between the silicon chips.

2. Related Art

In die-to-die integration and die-to-wafer integration in the field of three-dimensional packaging, simultaneous stacking of multiple silicon chips having a fine gap (of 10 μm or less) therebetween is one of important challenges to be achieved.

FIG. 1 is a schematic view showing how multiple silicon chips are stacked on one another.

In gaps between the multiple silicon chips, a number of solder bumps are arranged in arrays on the plane (in the lateral direction x and the depth direction y) of the silicon chips. In joining the silicon chips through a melting process of these many solder bumps, the silicon chips need to be aligned in the height direction with high accuracy.

In the die-to-wafer integration, a cavity method using a template is known as one of the simultaneous stacking methods using efficient passive alignment.

FIGS. 2A, 2B, and 2C are schematic views illustrating the cavity method using a template.

Multiple silicon chips are placed inside (inserted into) the template as shown in FIG. 2A, and the multiple silicon chips are enclosed by the template as shown in FIG. 2B. The passive alignment is achieved in this way.

FIG. 2C is a top view. As shown in FIG. 2C, stoppers can also be used as means for regulating the relative positions of the multiple silicon chips.

This cavity method has the advantage of achieving passive alignment and requiring few steps. However, the expectable alignment accuracy depends on the accuracy of dicing the silicon chips and on the size of clearance between the template and the silicon chips.

Generally, the accuracy of dicing silicon chips is on the order of several tens of micrometers. In consideration of clearance (10 to 20 μm) needed for placing (inserting) the silicon chips in the template, it is not easy to obtain an accuracy of 6σ<50 μm in general processes.

In the vertical gap (of 10 μm or less) between the multiple silicon chips, the solder bumps have a small height (each solder bump is small in size as a whole), and the pitch (the lateral interval) of the many solder bumps (arranged in arrays) is small.

Accordingly, it is hardly expected that a restoring force due to surface tensions of the melted solder bumps will allow self-alignment.

This is because, as long as the size of each solder bump is small, a restoring force expectable from each solder bump is small.

Japanese Patent Application Publication No. 2006-12883 discloses a technique for self-alignment (positioning) of joints which uses the effect of a restoring force utilizing the surface tensions of preferentially-melted solder. However, Japanese Patent Application Publication No. 2006-12883 does not use a technique of stoppers or standoffs.

Elemental techniques such as the stoppers or standoffs (also called studs hereinbelow) are well known, but in the technical field to which the present invention pertains, no example is found of a technique for achieving control of heights or (lateral) widths in the order of several micrometers to 5 μm.

In practice, forming the studs from resin requires different types of processes from those generally performed in the current three-dimensional packaging. In this sense, such elemental techniques have no compatibility with the processes of the three-dimensional packaging.

### SUMMARY OF THE INVENTION

One aspect of the invention includes a method for forming a plurality of studs configured to restrict lateral relative motion of a plurality of silicon chips when solder bumps are melted between the plurality of silicon chips. The method includes the steps of: setting a pitch and an accuracy of expected lateral shift for a plurality of solder bumps to be arranged between the plurality of silicon chips, determining lateral positions of target solder bumps based on the set pitch, using the determined lateral positions of the target solder bumps as a reference for determining (i) a first lateral position of each of a plurality of alignment solder bumps on a first one of the silicon chips and (ii) a second lateral position of each of a plurality of purposely-not-aligned solder bumps on a second one of the silicon chips, wherein the first and second lateral positions are determined such that an accuracy of relative shift between the first lateral position and the second lateral position is larger than the accuracy of expected lateral shift, using the determined lateral positions of the target solder bumps as a reference for determining lateral positions and lateral widths of a plurality of studs provided on the first silicon chip and the second silicon chip, respectively, wherein the positions and the widths are determined such that relative lateral motion of the plurality of silicon chips is restricted to bring the lateral positions of the plurality of solder bumps on the respective silicon chips into alignment via a height direction, and forming the studs having the determined lateral widths at the determined lateral positions on the first and second silicon chips, respectively.

Another aspect of the invention includes a combination of studs, silicon chips, and solder bumps configured to restrict lateral relative motion of a plurality of silicon chips when solder bumps are melted between the plurality of silicon chips, the combination includes: a plurality of studs, a plurality of silicon chips, and a plurality of target solder bumps, wherein the plurality of solder bumps are melted between the plurality of silicon chips, wherein lateral positions of the plurality of studs are arranged to accord with a pitch of the plurality of target solder bumps by using the pitch as a reference point, wherein (i) lateral positions and lateral widths of studs of the plurality of studs located at a first silicon chip of the plurality of silicon chips and (ii) lateral positions and lateral widths of studs of the plurality of studs located at a second silicon chip of the plurality of silicon chips are arranged such that relative lateral motion of at least the first and second of the plurality of silicon chips is restricted to bring the lateral positions of the plurality of solder bumps on the respective silicon chips in the vertical direction.

### BRIEF DESCRIPTION OF THE DRAWINGS

FIG. 1 illustrates a schematic view showing how multiple silicon chips are stacked on one another as known in the prior art.

FIG. 2A illustrates a schematic view illustrating a cavity method using a template as known in the prior art.

FIG. 2B illustrates a schematic view illustrating a cavity method using a template as known in the prior art.

FIG. 2C illustrates a schematic view illustrating a cavity method using a template as known in the prior art.

FIG. 3 illustrates a schematic view showing how studs formed with high accuracy according to the present invention are used to encourage accurate self-alignment of solder bumps according to the present invention.

FIG. 4 illustrates a schematic diagram illustrating the operations of accurate self-alignment of solder bumps, which uses the studs formed with high accuracy according to the present invention according to the present invention.

FIG. 5 illustrates a diagram showing a first example of forming studs, in which the studs are formed as intermetallic compounds (IMC) according to the present invention.

FIG. 6 illustrates a second example of forming studs, in which the studs are formed as solder paste using an inkjet method according to the present invention.

FIG. 7 illustrates a third example of forming studs, in which the studs are formed as metallic stud bumps according to the present invention.

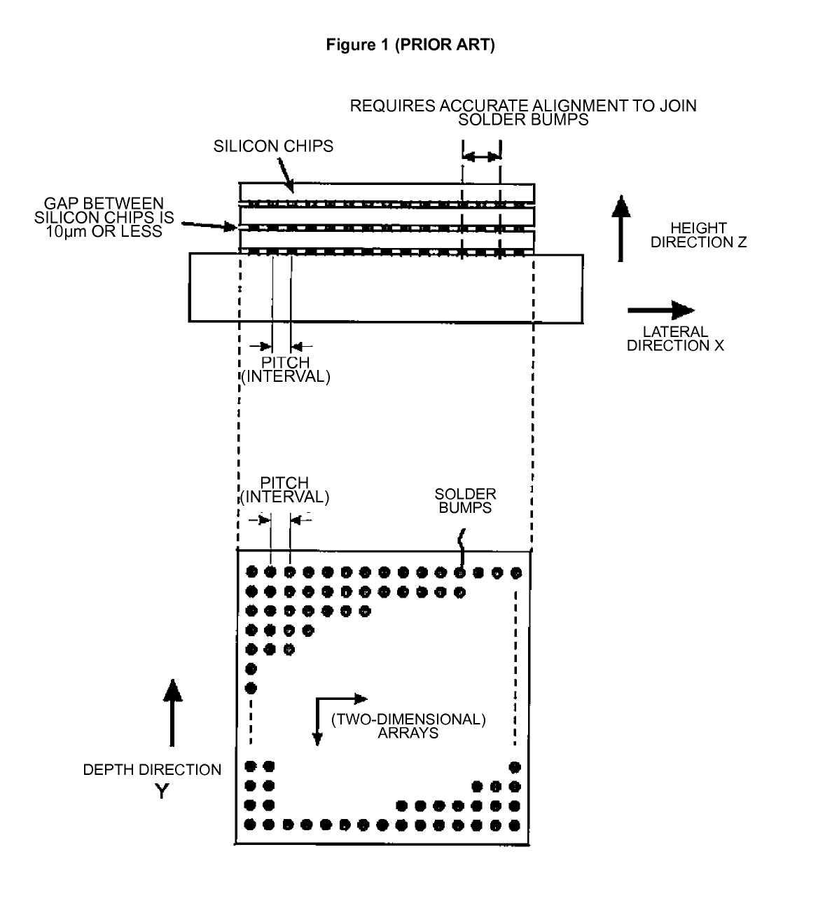

### DETAILED DESCRIPTION OF THE PREFERRED EMBODIMENTS

The present invention has an objective to provide accurate alignment which has compatibility with three-dimensional packaging processes.

The present invention provides a method for forming a plurality of studs configured to restrict lateral relative motion of a plurality of silicon chips when solder bumps are melted between the plurality of silicon chips, the method comprising the steps of: preparing the plurality of silicon chips; setting a pitch and an accuracy of expected lateral shift (Δx≈5 μm) of a plurality of solder bumps to be arranged between the plurality of silicon chips; determining lateral positions of target solder bumps (10) based on the set pitch; using the determined lateral positions of the target solder bumps (10) as a reference, determining a first lateral position of each of a plurality of alignment solder bumps (20) on a first one of the silicon chips and a second lateral position of each of a plurality of purposely-not-aligned solder bumps (30) on a second one of the silicon chips, the first and second lateral positions determined such that an accuracy of relative shift between the first lateral position and the second lateral position is larger than the accuracy of expected lateral shift (≈5 μm) (d>Δx); using the determined lateral positions of the target solder bumps (10) as a reference, determining lateral positions and (lateral) widths of a plurality of studs (40) provided on the first silicon chip and the second silicon chip, respectively, the positions and the widths determined such that relative lateral motion of the plurality of silicon chips is restricted to bring the lateral positions of the plurality of solder bumps on the respective silicon chips into alignment (in a height direction); and forming the studs (40) having the determined (lateral) widths at the determined lateral positions on the first and second silicon chips, respectively.

The present invention also provides a combination of a plurality of studs (40) configured to restrict lateral relative motion of a plurality of silicon chips when solder bumps are melted between the plurality of silicon chips, wherein lateral positions of the studs (40) are determined in accordance with a pitch of a plurality of target solder bumps (10) arranged between the plurality of silicon chips and by using lateral positions of the plurality of target solder bumps (10) as a reference, and lateral positions and (lateral) widths of the studs (40) on the first silicon chip and the second silicon chip, respectively, are determined such that relative lateral motion of the plurality of silicon chips is restricted to bring the lateral positions of the plurality of solder bumps on the respective silicon chips into alignment (in a height direction).

According to the present invention, accurate alignment having compatibility with the three-dimensional packaging processes is provided.

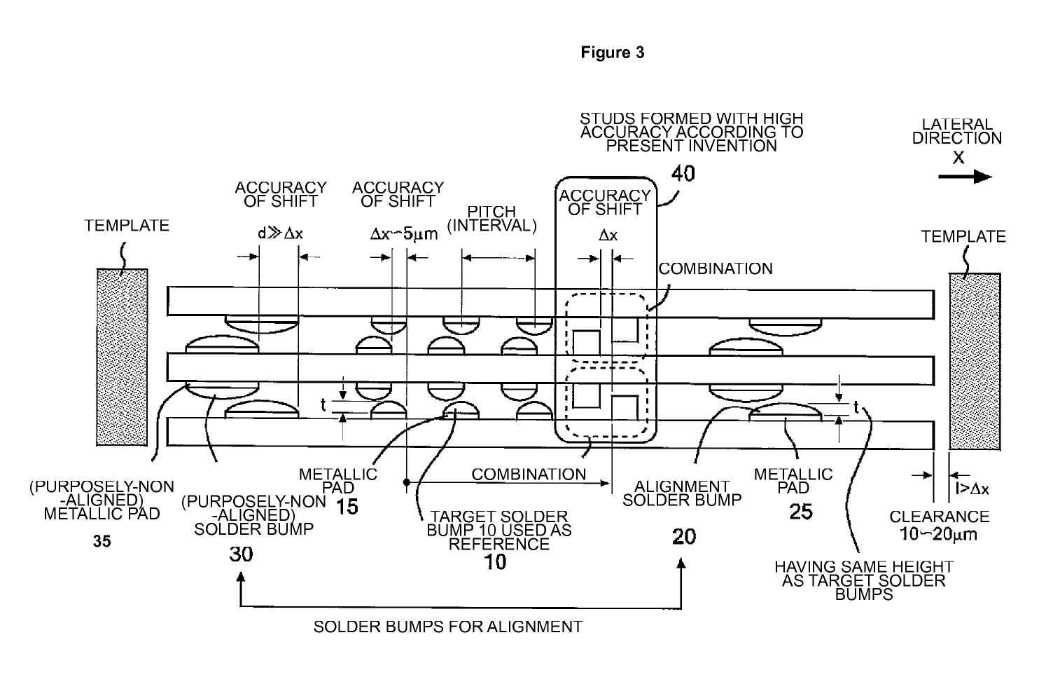

FIG. 3 is a schematic diagram showing how studs formed with high accuracy according to the present invention are used to encourage accurate self-alignment of solder bumps.

It should be noted that FIG. 3 is used for schematic descriptions and is therefore exaggerated in the size of each solder bump, which is very large, and in the number of the solder bumps, which is very small.

Once the number of bumps to be arranged in the lateral direction (i.e., the X direction) is determined, the pitch (interval) expected between them can be calculated.

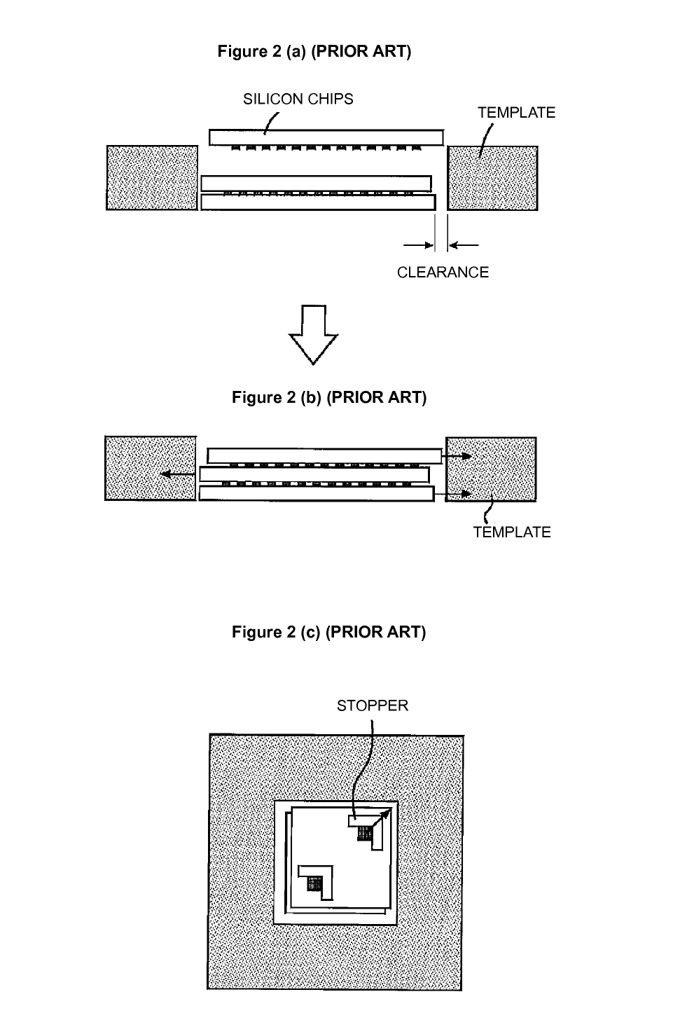

As an example of three-dimensional packaging (simultaneous stacking), FIG. 3 shows three silicon chips stacked on one another being placed inside (inserted into) a template. The cavity method using a template, described above with FIG. 2, is used here.

Accordingly, what needs to be considered is only a clearance (of 10 to 20 μm) necessary for placing the silicon chips inside the template (or necessary for allowing them to be inserted into the template). Accordingly, the processes can be started with relatively rough mounting of the silicon chips.

Three target solder bumps 10 are arranged in series in the lateral direction (i.e., the x direction), and these solder bumps are expected to be joined together in a gap between the multiple silicon chips in order to achieve the simultaneous stacking of the multiple silicon chips.

Since solder bumps are to be used not only for mechanical bonding between multiple silicon chips, but also for electrical bonding between them, the target solder bumps 10 are provided on metallic pads 15, respectively. Instead, unlike FIG. 3, one of the upper and lower sides can have solder bumps only, and the other side can have the metallic pads only.

By being melted, each solder bump liquefies and spreads on its corresponding metallic pad. In principle, the solder bump does not spread beyond the width of the metallic pad 15, and solidifies after the melting.

A solder bump 20 used for alignment (referred to as an alignment solder bump 20 herein below) is arranged on each of both sides of the target solder bumps 10.

The alignment solder bumps 20 are wider (in the lateral direction, i.e., the x direction) than the target bumps 10.

These solder bumps 20, too, are provided on metallic pads 25, respectively. The metallic pads 25 are also wider than the metallic pads 15.

Note that the middle one of the three stacked silicon chips is shifted to the left in the lateral direction (i.e., the x direction) relative to the other two silicon chips.

A specific amount of shift is connected with the accuracy of shift. The target solder bumps 10 on the middle silicon chip can be set to have an accuracy Δx≈5 μm. Note that an amount of shift d for the alignment solder bumps 20 is preferably set to d>>Δx (or d>Δx).

Purposely-not-aligned solder bumps 30 are provided on respective (purposely-not-aligned) metallic pads 35 on both sides of the middle silicon chip. With the solder bumps having the shift amounts set as above, the solder bumps 30, when melted, are expected to generate a surface tension and therefore a relatively large restoring force.

“Solder bumps for alignment” are a combination of one of the multiple alignment solder bumps 20 provided on one silicon chip and a corresponding one of the multiple purposely-not-aligned solder bumps 30 provided on another silicon chip.

Combinations of studs 40 formed with high accuracy according to the present invention are formed with an accuracy Δx≈5 μm, which is the same accuracy as the target solder bumps 10.

In other words, the positions to provide studs are determined based on the pitch for arranging the multiple solder bumps 10 or the metallic pads 15 and on its accuracy of shift (direction).

By using the pitch for arranging the solder bumps 10 or the metallic pads 15 as a reference, the positions of the studs can also be determined in a process of designing and forming the solder bumps. Accordingly, formation of the studs can be performed as an extension of (or using the opportunity of) the same process usually performed for silicon chips in the current three-dimensional packaging.

A sequence (or a step) for setting the values and a sequence (or a step) for determining the values can be carried out automatically using a computer. A procedure of the sequence of processes can be described in a program to be provided as a program.

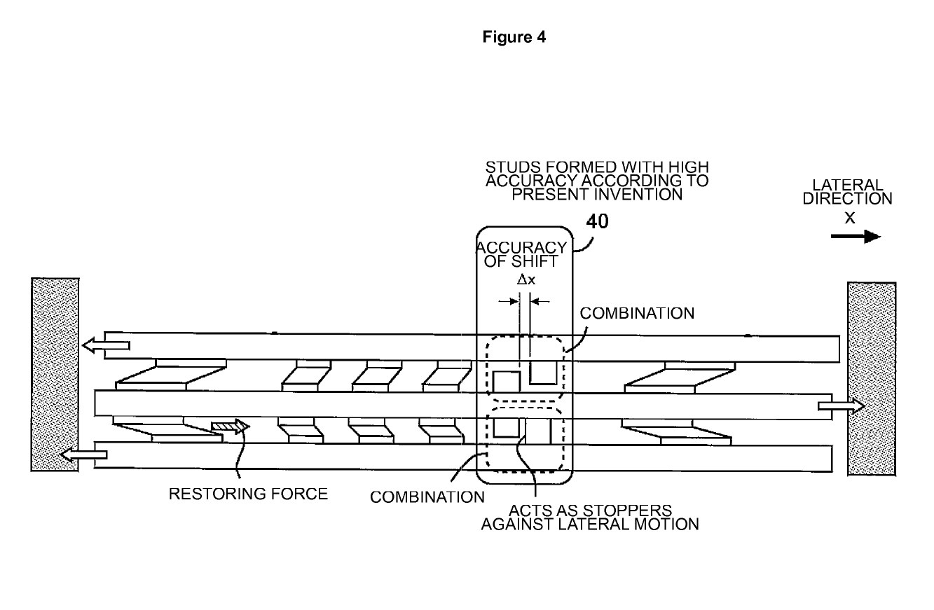

FIG. 4 is a schematic diagram illustrating the operations of accurate self-alignment of solder bumps, which uses the studs formed with high accuracy according to the present invention.

When melted, the solder bumps liquefy and spread on the respective metallic pads, and the solder thus melted connect between the multiple upper and lower metallic pads. A restoring force is generated by the effect of the surface tension of the solders.

The restoring force indicated by an arrow tries to push the middle silicon chip to the right unlimitedly, but (the combinations of) the studs formed with high accuracy according to the present invention act as stoppers against the lateral motion caused by the restoring force, and thereby restrict the lateral relative positions of the multiple silicon chips. The stoppers acting as such have significant purpose.

Since the stoppers are designed (or formed) to have the same accuracy Δx as the target bumps, the positions of the upper and lower target bumps align with each other (in the height direction). Thus, the alignment falls within the range of Δx with high accuracy.

When the target solder bumps 10 solidify, the alignment solder bumps 20 and the purposely-not-aligned solder bumps 30 also solidify. If they solidify under the expected accuracy, the solder bumps 20 and 30 still have a shift amount of d−Δx.

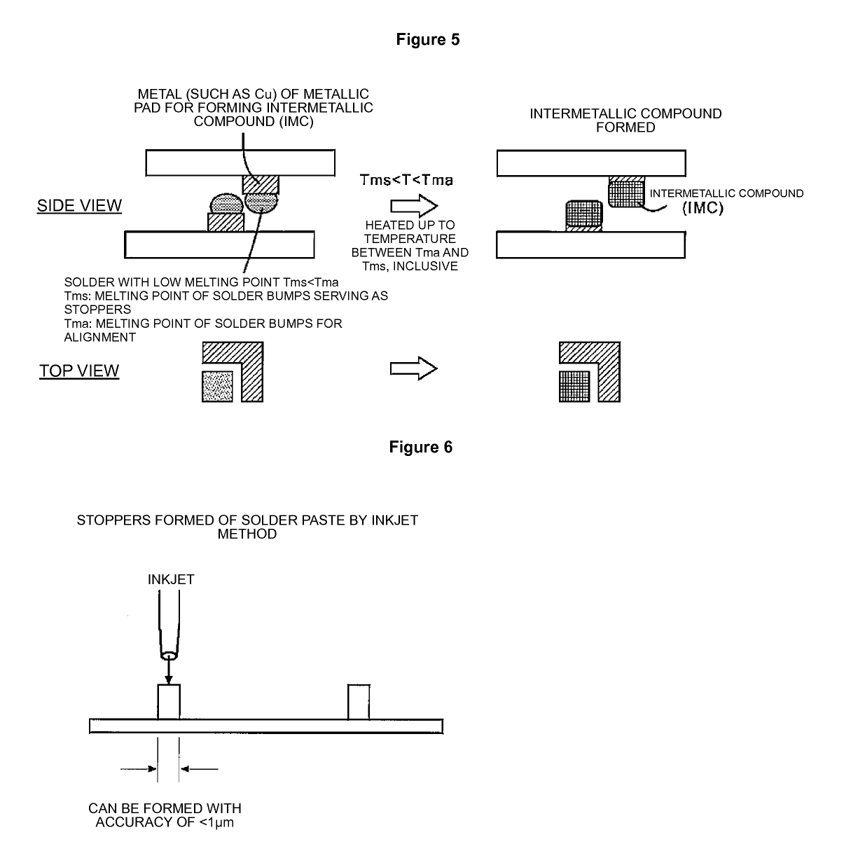

FIG. 5 is a diagram showing a first example of forming studs, in which the studs are formed as intermetallic compounds (IMC).

The melting point of the solder bumps serving as the studs (stoppers) (Tms) is set to be lower than the melting point of the solder bumps for alignment (Tma).

Thereby, when the semiconductor chips are heated to a temperature T of Tms<T<Tma, metal of the metallic pads and the solder bumps form intermetallic compounds.

It is known that, once the metallic pads and the solder bumps form intermetallic compounds (IMC), the melting point (Tmc) of the intermetallic compounds (IMC) exceeds the melting point (Tms) of the solder bumps having a low melting point, and therefore Tms<Tmc.

Here, the melting points are set to Tma<Tmc, so that the studs (Stoppers) do not melt even when the solder bumps for alignment are melted.

FIG. 6 shows a second example of forming studs, in which the studs are formed as solder paste using an inkjet method.

By using a technique for application of solder paste using an inkjet method, studs (stoppers) having a width with an accuracy of <1 μm (i.e., less than 1 μm) can be achieved.

The lateral positions and the (lateral) widths of the studs can be determined so that a combination of the studs provided on the respective upper and lower silicon chips restricts the relative motion of the silicon chips.

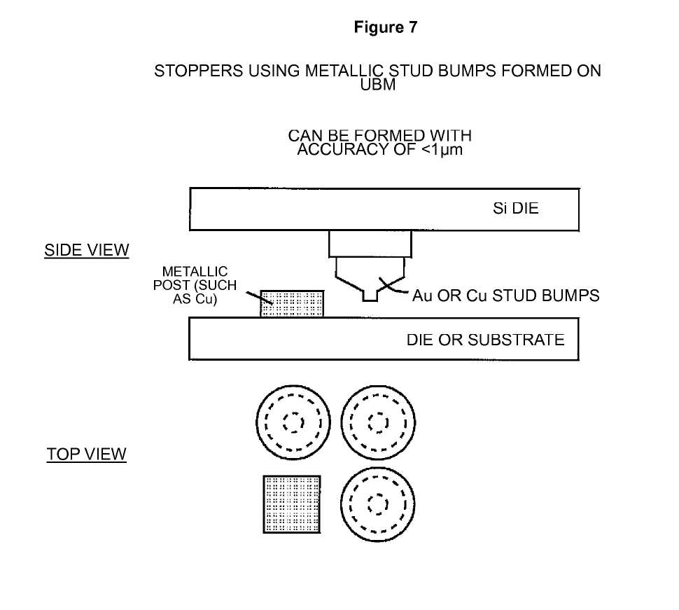

FIG. 7 is a third example of forming studs, in which the studs are formed as metallic stud bumps.

Semiconductor chip formation involves a sequence of processes such as providing Au or Cu wiring on a silicon (Si) die.

Formation of stud bumps made of Au or Cu can be performed as an extension of such a sequence, and therefore has compatibility with processes of three-dimensional packaging.

FIG. 7 illustrates stud bumps that have been formed by pulling up Au or Cu wires.

Formation of metallic posts (of Cu for example) also has compatibility with processes of three-dimensional packaging because three-dimensional packaging originally involves a sequence of processes such as providing Cu wiring.

What is claimed is:

1. A method for forming a plurality of studs configured to restrict lateral relative motion of a plurality of silicon chips when solder bumps are melted between the plurality of silicon chips, the method comprising the steps of:
setting a pitch and an accuracy of expected lateral shift for a plurality of solder bumps to be arranged between the plurality of silicon chips;
determining lateral positions of target solder bumps based on the set pitch;
using the determined lateral positions of the target solder bumps as a reference for determining (i) a first lateral position of each of a plurality of alignment solder bumps on a first one of the silicon chips and (ii) a second lateral position of each of a plurality of purposely-not-aligned solder bumps on a second one of the silicon chips, wherein the first and second lateral positions are determined such that an accuracy of relative shift between the first lateral position and the second lateral position is larger than the accuracy of expected lateral shift;
using the determined lateral positions of the target solder bumps as a reference for determining lateral positions and lateral widths of a plurality of studs provided on the first silicon chip and the second silicon chip, respectively, wherein the positions and the widths are determined such that relative lateral motion of the plurality of silicon chips is restricted to bring the lateral positions of the plurality of solder bumps on the respective silicon chips into alignment via a height direction; and
forming the studs having the determined lateral widths at the determined lateral positions on the first and second silicon chips, respectively.

2. The method according to claim 1, wherein in the forming the studs step, each stud is formed by causing metal of a metallic pad and a solder bump to form an intermetallic compound.

3. The method according to claim 2, wherein, the melting between the plurality of silicon chips is such that a melting point of the studs is set to be lower than a melting point of solder bumps for alignment, and wherein, in order to form an intermetallic compound, the metal of the metallic pad and the solder bump are heated to a temperature that is greater than a melting point of the studs but less than a melting point of the solder bumps for alignment.

4. The method according to claim 2, wherein the melting between the plurality of silicon chips is such that a melting point of the solder bumps for alignment is less than the melting point of the intermetallic compound.

5. The method according to claim 1, wherein the studs are formed by application of solder paste using an inkjet process.

6. The method according to claim 1, wherein the studs are formed as one of i) Au and ii) Cu stud bumps in an extended part of a sequence of processes.

7. A combination of studs, silicon chips, and solder bumps configured to restrict lateral relative motion of a plurality of silicon chips when solder bumps are melted between the plurality of silicon chips, the combination comprising:
a plurality of studs;
a plurality of silicon chips; and
a plurality of target solder bumps,
wherein the plurality of solder bumps are melted between the plurality of silicon chips,
wherein lateral positions of the plurality of studs are arranged to accord with a pitch of the plurality of target solder bumps by using the pitch as a reference point, wherein (i) lateral positions and lateral widths of studs of the plurality of studs located at a first silicon chip of the plurality of silicon chips and (ii) lateral positions and lateral widths of studs of the plurality of studs located at a second silicon chip of the plurality of silicon chips are arranged such that relative lateral motion of at least the first and second of the plurality of silicon chips is restricted to bring the lateral positions of the plurality of solder bumps on the respective silicon chips in the vertical direction.

8. The combination according to claim 7, wherein the combination of the silicon chips is placed inside a template and the lateral positions of the plurality of solder bumps on the respective silicon chips are in alignment in the vertical direction with an achieved accuracy of at least 5 micrometers.
